(19) United States
(12) Patent Application Publication
(10) Pub. No.: US 2024/0355794 A1
(43) Pub. Date: Oct. 24, 2024

(54) SEMICONDUCTOR PACKAGE AND METHOD FOR MANUFACTURING THE SAME

(71) Applicant: Samsung Electronics Co., Ltd., Suwon-si (KR)

(72) Inventors: Choongbin Yim, Suwon-si (KR); Jongkook Kim, Suwon-si (KR); Chengtar Wu, Suwon-si (KR)

(21) Appl. No.: 18/497,039

(22) Filed: Oct. 30, 2023

(30) Foreign Application Priority Data
Apr. 19, 2023 (KR) 10-2023-0051537

(51) Int. Cl. H01L 25/10; H01L 21/48; H01L 21/56; H01L 23/00; H01L 23/31; H01L 23/373; H01L 23/498; H10B 80/00

(52) U.S. Cl. CPC H01L 25/105; H01L 21/4857; H01L 21/565; H01L 23/3135; H01L 23/3738; H01L 23/49822; H01L 23/49894; H01L 24/08; H01L 24/16; H01L 24/32; H01L 24/73; H10B 80/00; H01L 24/83; H01L 2224/08145; H01L 2224/08235; H01L 2224/16145; H01L 2224/16227; H01L 2224/16235; H01L 2224/16238; H01L 2224/32145; H01L 2224/32225; H01L 2224/73204; H01L 2224/73253; H01L 2224/83862; H01L 2225/1035; H01L 2225/1041; H01L 2225/1058; H01L 2924/1436; H01L 2924/15153; H01L 2924/3511

(57) ABSTRACT

A semiconductor package may include: a redistribution layer structure; a semiconductor structure on the redistribution layer structure; a printed circuit board on the redistribution layer structure and extending around a side surface of the semiconductor structure; a molding material extending around the semiconductor structure on the redistribution layer structure; and a silicon interposer on the printed circuit board and the molding material.

### CROSS-REFERENCE TO RELATED APPLICATION(S)

This application claims priority under 35 U.S.C. § 119 to and the benefit of Korean Patent Application No. 10-2023-0051537 filed in the Korean Intellectual Property Office on Apr. 19, 2023, the entire contents of which are incorporated herein by reference.

### BACKGROUND

The present disclosure relates to a semiconductor package and a method for manufacturing the same.

A semiconductor industry sector seeks to improve integration density so that more passive or active devices may be integrated within a given region. However, development of technology for miniaturizing a circuit line width of a front end semiconductor process has gradually faced limitations so that the semiconductor industry sector is supplementing the limitations of the front end semiconductor process by developing a semiconductor package that protects a semiconductor chip at which an integrated circuit is formed, becomes lightweight, thin, miniaturized, high-speed, and multifunctional, and has high integration density.

When the semiconductor package becomes lightweight, thin, miniaturized, high-speed, and multifunctional, the semiconductor package consumes more electric power per unit volume so that a temperature inside the semiconductor package increases. Particularly, since a molding material and a back-side redistribution layer (BRDL) structure are disposed on a three-dimensional integrated circuit (3D IC) structure in a package-on-package (POP) that includes the 3D IC structure in a lower package, it is difficult to discharge heat generated in the 3D IC structure in an upwards direction.

In addition, in the POP, a memory structure that is an upper package is stacked on the BRDL structure. Therefore, considering a thickness of the memory structure to be additionally stacked, it is difficult to include another heat dissipation structure in the lower package since a thickness of the lower package cannot be greater than or equal to a certain level, and it is difficult to design the 3D IC structure that is made of a silicon material with higher thermal conductivity than that of a molding material and has a certain thickness or more.

As described above, if heat generated in the semiconductor package is not efficiently discharged in response to temperature increase of the semiconductor package due to improvement in integration density, particularly, in the POP, a thermal stress difference between structures of the POP may cause warpage in the package, and an operating speed of the semiconductor package may slow down so that a product reliability problem is caused.

### SUMMARY

An embodiment of the present disclosure provides a semiconductor package in which a silicon interposer replaces a back-side redistribution layer (BRDL) structure of a conventional POP in order to improve a thermal characteristic of the PoP.

Another embodiment of the present disclosure provides a semiconductor package in which a three-dimensional integrated circuit (3D IC) structure is attached to a silicon interposer using a conductive adhesive member in order to improve a thermal characteristic of a PoP.

Another embodiment of the present disclosure provides a semiconductor package in which a heat dissipation structure is disposed at a portion of a silicon interposer adjacent to a three-dimensional integrated circuit (3D IC) structure in order to improve a thermal characteristic of a PoP.

Another embodiment of the present disclosure provides a semiconductor package that a printed circuit board may structurally and electrically connect between a silicon interposer and a front-side redistribution layer (FRDL) structure by replacing conductive posts of a conventional POP with the printed circuit board in order to increase rigidity of the POP structure.

A semiconductor package according to an embodiment of the present disclosure may include: a redistribution layer structure; a semiconductor structure on the redistribution layer structure; a printed circuit board on the redistribution layer structure and extending around a side surface of the semiconductor structure; a molding material molding the semiconductor structure on the redistribution layer structure; and a silicon interposer on the printed circuit board and the molding material.

A semiconductor package according to another embodiment may include: a redistribution layer structure; a first semiconductor structure on the redistribution layer structure; a conductive adhesive member on the first semiconductor structure; a printed circuit board on the redistribution layer structure and extending around a side surface of the semiconductor structure; a molding material molding the semiconductor structure on the redistribution layer structure; a silicon interposer on the conductive adhesive member, the printed circuit board, and the molding material; and a second semiconductor structure on the silicon interposer.

A method for manufacturing a semiconductor package according to an embodiment may include: attaching a printed circuit board including a through opening to a first surface of a silicon interposer; attaching a semiconductor structure to the first surface of the silicon interposer and within the through opening with a conductive adhesive member; molding the semiconductor structure with a molding material; and forming a redistribution layer structure on the molding material and the printed circuit board.

According to an embodiment, a back-side redistribution layer (BRDL) structure of a conventional POP may be replaced with a silicon interposer so that a thermal characteristic and warpage of the POP are improved, the number of steps in a redistribution layer process is reduced, and a manufacturing cost is reduced.

According to another embodiment, a 3D IC structure may be attached to a silicon interposer using a conductive paste, and a heat dissipation structure may be disposed at a portion of the silicon interposer adjacent to the 3D IC structure. Thus, the thermal characteristic of a POP may be improved.

According to another embodiment, conductive posts of a conventional POP may be replaced with a printed circuit board so that the printed circuit board is structurally and electrically connected between a silicon interposer and an FRDL structure. Thus, rigidity of a POP structure may be improved.

### BRIEF DESCRIPTION OF THE DRAWINGS

The accompanying drawings, which are included to provide a further understanding of the invention and are incorporated in and constitute a part of this application, are presented by way of example only and without limitation, wherein like reference numerals (when used) indicate corresponding elements throughout the several views, and wherein:

FIG. 1 is a cross-sectional view illustrating a semiconductor package in which a three dimensional integrated circuit (3D IC) structure is disposed on a front side redistribution layer structure through a connection terminal, the 3D IC structure is disposed within a through opening of a printed circuit board having two layers of vias, and a silicon interposer is disposed on the 3D IC structure and the printed circuit board.

FIG. 2 is a cross-sectional view illustrating a semiconductor package in which the 3D IC structure is disposed on the front side redistribution layer structure through the connection terminal, the 3D IC structure is disposed within the through opening of the printed circuit board having three layers of vias, and the silicon interposer is disposed on the 3D IC structure and the printed circuit board.

FIG. 3 is a cross-sectional view illustrating a semiconductor package in which the 3D IC structure is directly disposed on the front side redistribution layer structure without the connection terminal, the 3D IC structure is disposed within the through opening of the printed circuit board having the two layers of vias, and the silicon interposer is disposed on the 3D IC structure and the printed circuit board.

FIG. 4 is a cross-sectional view illustrating a semiconductor package including the 3D IC structure in which a first semiconductor die and a second semiconductor die are bonded by hybrid bonding in which the 3D IC structure is disposed on the front side redistribution layer structure through the connection terminal, the 3D IC structure is disposed within the through opening of the printed circuit board having the two layers of vias, and the silicon interposer is disposed on the 3D IC structure and the printed circuit board.

FIGS. 5 to 7 and 10 to 13 are cross-sectional views illustrating intermediate processes in an example method for manufacturing the 3D IC structure in which the first semiconductor die and the second semiconductor die are bonded by flip-chip bonding. FIG. 5 is a cross-sectional view showing a step of attaching the first semiconductor die on a first carrier as one of steps of a method for manufacturing the 3D IC structure.

FIG. 6 is a cross-sectional view showing a step of attaching an insulating member on the first semiconductor die as one of the steps of the method for manufacturing the 3D IC structure.

FIG. 7 is a cross-sectional view showing a step of mounting the second semiconductor die on the first semiconductor die as one of the steps of the method for manufacturing the 3D IC structure.

FIG. 8 is a cross-sectional view showing a step of attaching the first semiconductor die on the first carrier as one of the steps of the method for manufacturing the 3D IC structure. FIGS. 8 and 9 are cross-sectional views showing the method for manufacturing the 3D IC structure in which the first semiconductor die and the second semiconductor die are bonded by hybrid bonding.

FIG. 9 is a cross-sectional view showing a step of bonding the first semiconductor die and the second semiconductor die by hybrid bonding as one of the steps of the method for manufacturing the 3D IC structure. The method for manufacturing the 3D IC structure in which the first semiconductor die and the second semiconductor die are bonded by the flip chip bonding of FIGS. 10 to 13 may be equally applied to manufacturing methods after FIG. 9 among the method for manufacturing the 3D IC structure by the hybrid bonding.

FIG. 10 is a cross-sectional view showing a step of molding the second semiconductor die on the first semiconductor die with a second molding material as one of the steps of the method for manufacturing the 3D IC structure.

FIG. 11 is a cross-sectional view illustrating a step of planarizing an upper surface of the second molding material as one of the steps of the method for manufacturing the 3D IC structure.

FIG. 12 is a cross-sectional view illustrating a step of debonding the first carrier from the 3D IC structure as one of the steps of the method for manufacturing the 3D IC structure.

FIG. 13 is a cross-sectional view showing a step of forming connection terminals on a lower surface of the first semiconductor die as one of the steps of the method for manufacturing the 3D IC structure.

FIG. 14 is a cross-sectional view showing a step of attaching the silicon interposer on a second carrier as one of steps of a method for manufacturing the semiconductor package.

FIG. 15 is a cross-sectional view showing a step of attaching the printed circuit board on the silicon interposer as one of the steps of the method for manufacturing the semiconductor package.

FIG. 16 is a cross-sectional view showing a step of attaching the 3D IC structure including the connection terminals above the silicon interposer using a conductive adhesive member as one of the steps of the method for manufacturing the semiconductor package, and follows FIG. 15.

FIG. 17 is a cross-sectional view showing a step of attaching the 3D IC structure not including the connection terminals on the silicon interposer using the conductive adhesive member as one of the steps of the method for manufacturing the semiconductor package, and follows FIG. 15.

FIG. 18 is a cross-sectional view showing a step of attaching the 3D IC structure in which the first semiconductor die and the second semiconductor die are bonded by the hybrid bonding on the silicon interposer using the conductive adhesive member as one of the steps of the method for manufacturing the semiconductor package, and follows FIG. 15. A manufacturing method of FIGS. 19 to 24 may be equally applied to manufacturing methods after FIG. 18 among the method for manufacturing the semiconductor package including the 3D IC structure bonded by the hybrid bonding.

FIG. 19 is a cross-sectional view showing a step of molding the 3D IC structure including the connection terminals with a first molding material as one of the steps of the method for manufacturing the semiconductor package, and follows FIG. 16.

FIG. 20 is a cross-sectional view showing a step of molding the 3D IC structure not including the connection terminals with the first molding material as one of the steps of the method for manufacturing the semiconductor package, and follows FIG. 17.

FIG. 21 is a cross-sectional view showing a step of forming the front side redistribution layer structure on the first molding material and the printed circuit board as one of the steps of the method for manufacturing the semiconductor package, and follows FIG. 19.

FIG. 22 is a cross-sectional view showing a step of forming the front side redistribution layer structure to be directly bonded with a lower surface of the 3D IC structure on the first molding material and the printed circuit board as one of the steps of the method for manufacturing the semiconductor package, and follows FIG. 20. A manufacturing method of FIGS. 23 and 24 may be equally applied to a manufacturing method after FIG. 22 among the method for manufacturing the semiconductor package including the 3D IC structure that does not include the connection terminals.

FIG. 23 is a cross-sectional view showing a step of forming an external connection structure on the front side redistribution layer structure as one of the steps of the method for manufacturing the semiconductor package, and follows FIG. 21.

FIG. 24 is a cross-sectional view showing a step of debonding the second carrier from the silicon interposer as one of the steps of the method for manufacturing the semiconductor package.

### DETAILED DESCRIPTION OF EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those dimensions illustrated in the drawings.

Throughout the specification, when a part is “connected” to another part, it includes not only a case where the part is “directly connected” but also a case where the part is “indirectly connected” with another part in between. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a semiconductor package and a method for manufacturing the same according to an embodiment will be described with reference to the drawings.

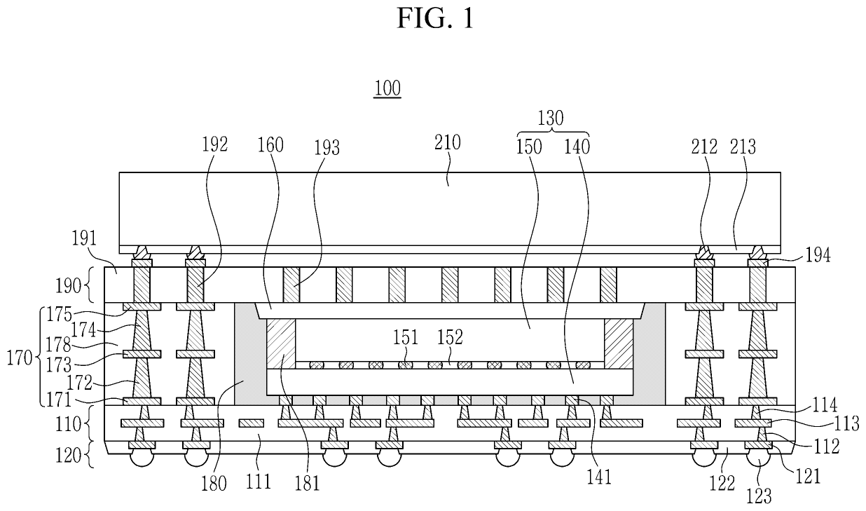

FIG. 1 is a cross-sectional view illustrating a semiconductor package 100 in which a three-dimensional integrated circuit (3D IC) structure 130 is disposed on a front-side redistribution layer (FRDL) structure 110 using at least one connection terminal 141, the 3D IC structure is disposed within a through opening of a printed circuit board 170 having two layers of vias, and a silicon interposer 190 is disposed on the 3D IC structure 130 and the printed circuit board 170.

Referring to FIG. 1, the semiconductor package 100 may include the front-side redistribution layer structure 110, an external connection structure 120, the 3D IC structure 130 including at least a first semiconductor die 140 and a second semiconductor die 150, the printed circuit board 170, a first molding material 180, the silicon interposer 190, and a memory structure (a third semiconductor die) 210.

In an embodiment, the semiconductor package 100 may include a package-on-package (POP). In an embodiment, the semiconductor package 100 may include a fan-out wafer level package (FOWLP) or a fan-out panel level package (FOPLP).

The front-side redistribution layer structure 110 may include a dielectric layer 111, first redistribution layer vias 112, first redistribution layer lines 113, and second redistribution layer vias 114 within the dielectric layer 111. In another embodiment, a redistribution layer structure including a fewer or greater number of redistribution layer lines and a fewer or greater number of redistribution layer vias is included within a scope of the present disclosure.

The dielectric layer 111 protects and insulates the first redistribution layer vias 112, the first redistribution layer lines 113, and the second redistribution layer vias 114. The 3D IC structure 130 including the first semiconductor die 140 and the second semiconductor die 150, and the printed circuit board 170 may be disposed on an upper surface of the dielectric layer 111. The external connection structure 120 may be disposed on a lower surface of the dielectric layer 111.

The first redistribution layer via 112 may be disposed between the first redistribution layer line 113 and a conductive pad 121 of the external connection structure 120. The first redistribution layer via 112 may electrically connect the first redistribution layer line 113 and the conductive pad 121 in a vertical direction. The first redistribution layer line 113 may be disposed between the first redistribution layer via 112 and the second redistribution layer via 114. The first redistribution layer line 113 may electrically connect the first redistribution layer via 112 and the second redistribution layer via 114 in a horizontal direction, perpendicular to the vertical direction. The second redistribution layer via 114 may be disposed between the first redistribution layer line 113 and a first wire layer 171 of the printed circuit board 170. The second redistribution layer via 114 may electrically connect the first redistribution layer line 113 and the first wire layer 171 of the printed circuit board 170 in a vertical direction.

The external connection structure 120 may be disposed on a lower surface of the front-side redistribution layer structure 110. The external connection structure 120 may include conductive pads 121, an insulating layer 122, and external connection members 123. The conductive pads 121 may electrically connect the first redistribution layer via 112 of the front side redistribution layer structure 110 and the external connection members 123. The insulating layer 122 may include a plurality of openings for soldering. The insulating layer 122 prevents the external connection members 123 from being short-circuited to one another. The external connection members 123 may electrically connect the semiconductor package 100 to an external device.

The 3D IC structure (a semiconductor structure) 130 may be disposed on an upper surface of the front-side redistribution layer structure 110. The 3D IC structure 130 may include the first semiconductor die 140 and the second semiconductor die 150. In an embodiment, the 3D IC structure 130 may include a system-on-chip (SoC).

The first semiconductor die 140 may be disposed on the upper surface of the front-side redistribution layer structure 110. In an embodiment, the first semiconductor die 140 may include a central processing unit (CPU) or a graphics processing unit (GPU). The first semiconductor die 140 may include the connection terminal(s) 141, and may be electrically connected to the second redistribution layer via 114 of the front-side redistribution layer structure 110 through the connection terminal(s) 141.

In the 3D IC structure 130 including the first semiconductor die 140 and the second semiconductor die 150 on the first semiconductor die 140, the second semiconductor die 150 may be disposed spaced apart, in the vertical direction, from the front-side redistribution layer structure 110 that transfers a signal and electric power. Thus, through silicon vias (TSV) (not explicitly shown, but implied) may be disposed within the first semiconductor die 140 and the through silicon vias (TSV) may be connected to the second semiconductor die 150 so that a speed at which the second semiconductor die 150 receives a signal and electric power and responds to the signal and the electric power is increased.

The second semiconductor die 150 may be disposed on an upper surface of the first semiconductor die 140. In an embodiment, the second semiconductor die 150 may include a communication chip or a sensor. The second semiconductor die 150 may include connection members 151, and may be electrically connected to the first semiconductor die 140 through the connection members 151. In an embodiment, the connection member 151 may include a micro-bump. An insulating member 152 may be disposed between the first semiconductor die 140 and the second semiconductor die 150, and between adjacent connection members 151. The insulating member 152 serves to surround (i.e., extend around) and insulate the connection members 151 between the first semiconductor die 140 and the second semiconductor die 150. In an embodiment, the insulating member 152 may include a non-conductive film (NCF).

A second molding material 181 may mold (i.e., encapsulate or extend around) the second semiconductor die 150 and the insulating member 152 on the first semiconductor die 140. In an embodiment, the second molding material 181 may include an epoxy molding compound (EMC).

A conductive adhesive member 160 may be disposed between the second semiconductor die 150 of the 3D IC structure 130 and the silicon interposer 190, and may be attached to the second semiconductor die 150 and the silicon interposer 190. The conductive adhesive member 160 may be made of a material having higher thermal conductivity than those of the first molding material 180 and the second molding material 181. Thermal conductivity may be defined as the rate at which heat is transferred, such as by conduction, through a unit cross-sectional area of a material, when a temperature gradient exits perpendicular to the area. In an embodiment, the conductive adhesive member 160 may include a conductive paste. In an embodiment, the conductive paste may include conductive powder, a thermosetting resin, a solvent, and the like. In an embodiment, the conductive powder may include at least one of copper, nickel, silver, gold, aluminum, titanium, tantalum, and tungsten. In an embodiment, the thermosetting resin may include an epoxy resin, a phenolic resin, or an acrylic resin.

In an embodiment, the conductive adhesive member 160 may include a thermal interface material (TIM). The thermal interface material (TIM) is a material inserted between a heat discharging device (e.g., the second semiconductor die 150) and a heat dissipating device (e.g., the silicon interposer 190) to improve thermal coupling. Thermal interface material (TIM) serves to reduce the thermal contact resistance by filling the air layer of the contact surface between the heat discharging device and the heat dissipating device. In an embodiment, the thermal interface material (TIM) may include a thermal paste, a thermal pad, a phase change material (PCM), or a metal material. In an embodiment, the thermal interface material (TIM) may include a grease.

The conductive adhesive member 160 may be disposed on the second semiconductor die 150 to discharge heat generated from the second semiconductor die 150. In the 3D IC structure 130, heat may accumulate on an upper surface of the second semiconductor die 150. Accordingly, the conductive adhesive member 160 may be disposed on the upper surface of the second semiconductor die 150 to discharge heat accumulated at the second semiconductor die 150.

A first surface of the conductive adhesive member 160 may physically contact the upper surface of the second semiconductor die 150, and a second surface of the conductive adhesive member 160 opposite to the first surface of the conductive adhesive member 160 may contact a lower surface of the silicon interposer 190. Due to this, the heat accumulated in the second semiconductor die 150 may be discharged through a path to be conducted to the first surface of the conductive adhesive member 160 physically in contact with the second semiconductor die 150, and the conducted heat may pass through the conductive adhesive member 160, and then, be conducted to the silicon poser 190 via the second surface of the conductive adhesive member 160.

The printed circuit board 170 may be disposed on the upper surface of the front-side redistribution layer structure 110. The printed circuit board 170 may include the through opening, and the 3D IC structure 130 may be disposed within the through opening. The printed circuit board 170 may surround a side surface of the 3D IC structure 130. In an embodiment, the printed circuit board 170 may include an embedded trace substrate (ETS).

The printed circuit board 170 may include the first wire layer 171, a first via 172, a second wire layer 173, a second via 174, a third wire layer 175, and an insulation layer 178. The printed circuit board 170 may be disposed between the front-side redistribution layer structure 110 and the silicon interposer 190, and may electrically connect the front side redistribution layer structure 110 and the silicon interposer 190. As described above, according to the present disclosure, the semiconductor package 100 having improved rigidity and high reliability may be provided by replacing conductive posts of a conventional package-on-package (POP) with the printed circuit board 170.

The first molding material 180 may mold (i.e., encapsulate or extend around) the 3D IC structure 130 and the conductive adhesive member 160 on the front-side redistribution layer structure. In an embodiment, the first molding material 180 may include an epoxy molding compound (EMC).

The silicon interposer 190 may be disposed on the conductive adhesive member 160, the printed circuit board 170, and the first molding material 180. The silicon interposer 190 may include a base substrate 191, first through silicon vias (TSV) 192 and second through silicon vias (TSV) 193 penetrating the base substrate 191, and connection pads 194. The base substrate 191 may be a wafer level substrate made of silicon. The first through silicon vias (TSV) 192 may be disposed between the third wire layer 175 of the printed circuit board 170 and the connection pad 194, and may electrically connect the third wire layer 175 of the printed circuit board 170 and the connection pad 194.

The second through silicon vias (TSV) 193, or at least a subset thereof, may serve as a heat dissipation structure. A first end of the second through silicon vias (TSV) 193 may physically contact the conductive adhesive member 160, and a second end of the second through silicon vias (TSV) 193, opposite the first end, may be exposed to the outside. Heat transferred from the second semiconductor die 150 to the conductive adhesive member 160 may be conducted to the first end of the second through silicon vias (TSV) 193, and the conducted heat may pass through the second through silicon vias (TSV) 193 to be discharged through the second end of the second through silicon vias (TSV) 193. Each of at least a subset of the second through silicon vias (TSV) 193 may be electrically insulated. In another embodiment, the silicon interposer 190 may not include the second through silicon vias (TSV) 193.

The connection pad 194 may be disposed between the first through silicon via (TSV) 192 and an external connection member 212 of the memory structure (the third semiconductor die) 210, and may electrically connect the first through silicon via (TSV) 192 and the external connection member 212 of the memory structure (the third semiconductor die) 210.

A back-side redistribution layer (BRDL) structure includes a dielectric layer using a photoimageable dielectric (PID) as a main material. A polymer composite material such as the photoimageable dielectric (PID) has a thermal conductivity of less than about 1 W/mk. In comparison, silicon of the silicon interposer 190 has a thermal conductivity of about 83.7 W/mK. Thus, the thermal conductivity of silicon has a greater value than that of the photoimageable dielectric (PID). Therefore, according to the present disclosure, heat accumulated at the 3D IC structure 130 may be more effectively discharged through the silicon interposer 190 by replacing a back-side redistribution layer structure of the conventional package-on-package (POP) with the silicon interposer 190.

In addition, the second through silicon vias (TSV) 193 penetrating the base substrate 191 and including a metal may be disposed on the conductive adhesive member (or a conductive paste) 160 within the silicon interposer 190 so that the heat accumulated at the 3D IC structure 130 is effectively discharged to the outside through the second through silicon vias (TSV) 193. In this case, the second through silicon vias (TSV) 193 function as the heat dissipation structure.

In addition, according to the present disclosure, the back-side redistribution layer structure of the conventional package-on-package (POP) may be replaced with the silicon interposer 190 so that a manufacturing process of the back-side redistribution layer structure for forming a plurality of fine patterns is omitted. Thus, the number of steps in a redistribution layer process may be reduced, and a manufacturing cost may be reduced.

The memory structure (the third semiconductor die) 210 may be disposed on the silicon interposer 190. The memory structure 210 may include a single chip such as a DRAM or a multichip such as a high-bandwidth memory (HBM). The memory structure 210 may include connection members 212 and an insulating layer 213. The connection members 212 may be disposed between the memory structure 210 and the silicon interposer 190, and may electrically connect the memory structure 210 and the silicon interposer 190. In an embodiment, the connection member 212 may include a micro-bump or a solder ball. The insulating layer 213 may include a plurality of openings for soldering. The insulating layer 213, which may be disposed between adjacent connection members 212, prevents the connection members 212 from being short-circuited to one another. In an embodiment, the insulating layer 213 may include a solder resist.

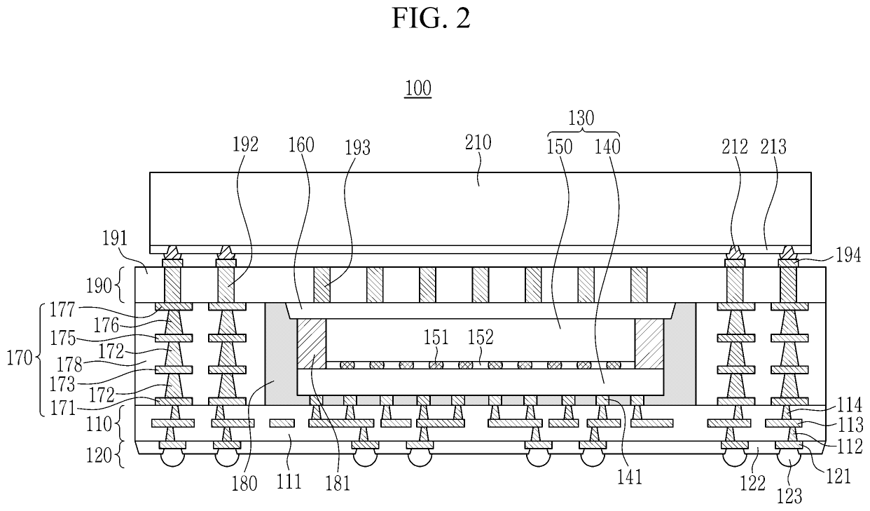

FIG. 2 is a cross-sectional view illustrating the semiconductor package 100 in which the 3D IC structure 130 is disposed on the front side redistribution layer structure 110 through the connection terminal 141, the 3D IC structure 130 is disposed within the through opening of the printed circuit board 170 having three layers of vias, and the silicon interposer 190 is disposed on the 3D IC structure 130 and the printed circuit board 170. It is to be appreciated that embodiments of the present disclosure are not limited to any specific number of wire layers or vias.

Referring to FIG. 2, the printed circuit board 170 may further include a third via 176 and a fourth wire layer 177 in addition to the first wire layer 171, the first via 172, the second wire layer 173, the second via 174, the third wire layer 175, and the insulation layer 178. In the embodiment of FIG. 1, the printed circuit board 170 includes the two layers of vias, but in the embodiment of FIG. 2, the printed circuit board 170 includes the three layers of vias. In another embodiment, the printed circuit board 170 including a fewer or greater number of wire layers and a fewer or greater number of vias is included within a scope of the present disclosure.

Another configuration other than the example configuration of FIG. 2 in which the printed circuit board 170 includes the three layers of vias is the same as the configuration described with reference to FIG. 1. Accordingly, contents described with reference to FIG. 1 may be equally applied to the other configuration other than the configuration of FIG. 2 in which the printed circuit board 170 includes the three layers of vias.

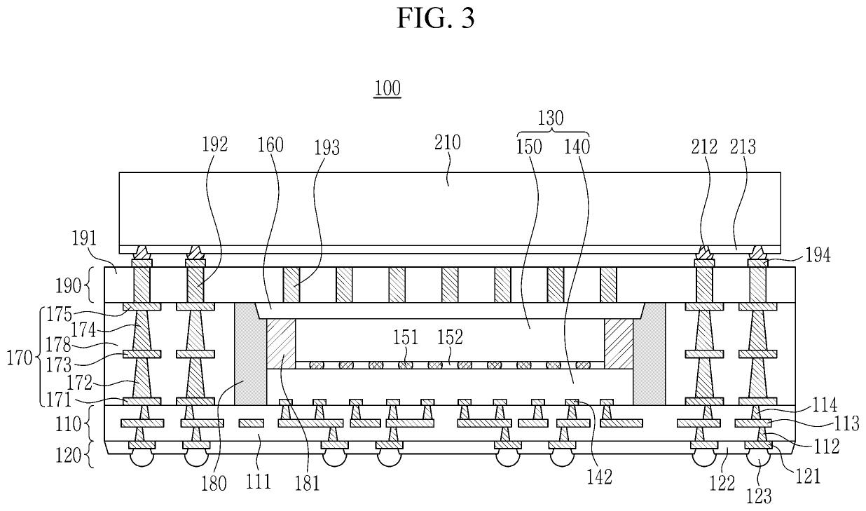

FIG. 3 is a cross-sectional view illustrating the semiconductor package 100 in which the 3D IC structure 130 is directly disposed on the front side redistribution layer structure 110 without a connection terminal, the 3D IC structure is disposed within the through opening of the printed circuit board 170 having the two layers of vias, and the silicon interposer 190 is disposed on the 3D IC structure 130 and the printed circuit board 170.

Referring to FIG. 3, the 3D IC structure 130 may be directly disposed on the front side redistribution layer structure 110 without the connection terminal 141 (FIG. 1). In the embodiment of FIG. 1, the 3D IC structure 130 is disposed on the front side redistribution layer structure 110 through the connection terminal 141, but in the embodiment of FIG. 3, the 3D IC structure 130 is directly disposed on the front side redistribution layer structure 110 without the connection terminal. A lower surface of the first semiconductor die 140 of the 3D IC structure 130, a lower surface of the printed circuit board 170, and a lower surface of the first molding material 180 may be disposed at the same level, in the vertical direction (i.e., coplanar). The second redistribution layer vias 114 disposed at an uppermost level of the front side redistribution layer structure 110 may directly contact the 3D IC structure 130.

Another configuration other than a configuration of FIG. 3 in which the 3D IC structure 130 is directly disposed on the front side redistribution layer structure 110 without the connection terminal is the same as the configuration described with reference to FIG. 1. Therefore, the contents described with reference to FIG. 1 may be equally applied to the other configuration other than the configuration of FIG. 3 in which the 3D IC structure 130 is directly disposed on the front side redistribution layer structure 110 without the connection terminal.

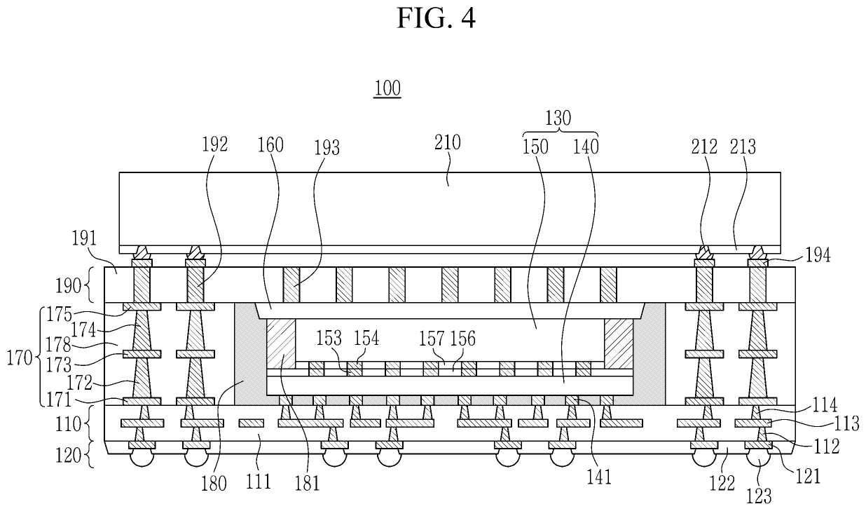

FIG. 4 is a cross-sectional view illustrating the semiconductor package 100 including the 3D IC structure 130 in which the first semiconductor die 140 and the second semiconductor die 150 are bonded by hybrid bonding in which the 3D IC structure 130 is disposed on the front side redistribution layer structure 110 through the connection terminal 141, the 3D IC structure is disposed within the through opening of the printed circuit board 170 having the two layers of vias, and the silicon interposer 190 is disposed on the 3D IC structure 130 and the printed circuit board 170.

Referring to FIG. 4. the semiconductor package 100 may include the 3D IC structure 130 in which the first semiconductor die 140 and the second semiconductor die 150 are bonded by the hybrid bonding. The first semiconductor die 140 may include first bonding pads 153 and a first silicon insulating layer 156 on an upper surface of the first semiconductor die, the first silicon insulating layer 156 being disposed between adjacent first bonding pads 153 for insulating the first bonding pads 153 from one another. The second semiconductor die 150 may include second bonding pads 154 and a second silicon insulating layer 157 on a lower surface of the second semiconductor die, the second silicon insulating layer 157 being disposed between adjacent second bonding pads 154 for insulating the second bonding pads 154 from one another. The first bonding pads 153 of the first semiconductor die 140 may be aligned with (in the vertical direction) and directly bonded to corresponding second bonding pads 154 of the second semiconductor die 150 by metal-metal hybrid bonding, and the first silicon insulating layer 156 of the first semiconductor die 140 may be directly bonded to the second silicon insulating layer 157 of the second semiconductor die 150 by non-metal-non-metal hybrid bonding.

Another configuration other than a configuration of FIG. 4 in which the first semiconductor die 140 and the second semiconductor die 150 are bonded by the hybrid bonding is the same as the configuration described with reference to FIG. 1. Accordingly, the contents described with reference to FIG. 1 may be equally applied to the other configuration other than the configuration of FIG. 4 in which the first semiconductor die 140 and the second semiconductor die 150 are bonded by the hybrid bonding.

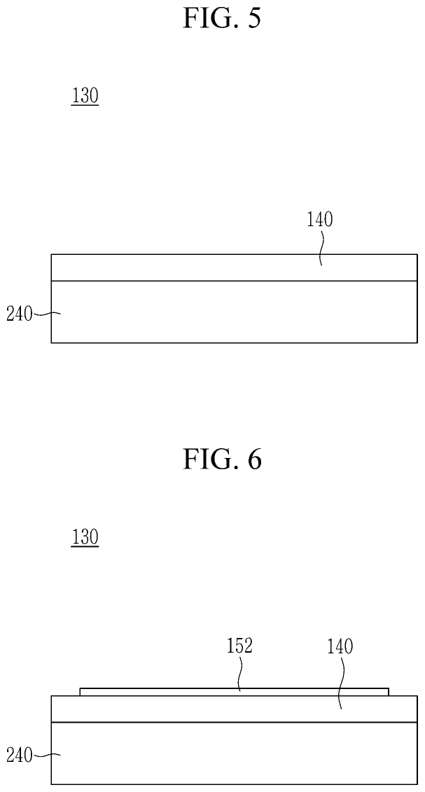

FIGS. 5 to 7 and 10 to 13 are cross-sectional views illustrating intermediate process steps in an example method for manufacturing the 3D IC structure 130 in which the first semiconductor die 140 and the second semiconductor die 150 are bonded by flip-chip bonding, according to one or more embodiments. FIG. 5 is a cross-sectional view showing a step of attaching the first semiconductor die 140 on a first carrier 240 as one of the intermediate steps of the example method for manufacturing the 3D IC structure 130.

Referring to FIG. 5, the first semiconductor die 140 is attached on the first carrier 240. The first carrier 240 may include a silicon-based material such as glass or a silicon oxide, another material such as an organic material or an aluminum oxide, any combination thereof, or the like.

Through silicon vias (not explicitly shown, but implied) may be formed in the first semiconductor die 140. The through silicon via forms a hole penetrating an insulating material within the first semiconductor die 140, and fills the hole with a conductive material. The term “fills” (or “filling,” “filled,” or like terms) as may be used herein is intended to refer broadly to either completely filling a defined space (e.g., through silicon via hole) or partially filling the defined space; that is, the defined space need not be entirely filled but may, for example, be partially filled or have voids or other spaces throughout. In an embodiment, the hole formed in the first semiconductor die 140 may be formed by deep etching. In another embodiment, the hole formed in the first semiconductor die 140 may be formed by a laser. In an embodiment, the hole formed in the first semiconductor die 140 may be filled with a conductive material by electrolytic plating. In an embodiment, the through silicon via may include at least one of tungsten, aluminum, copper, and an alloy thereof.

A barrier layer (not explicitly shown) may be formed between the through silicon via and an insulating material of the first semiconductor die 140. In an embodiment, the barrier layer may include at least one of titanium, tantalum, a titanium nitride, a tantalum nitride, and an alloy thereof.

FIG. 6 is a cross-sectional view showing a step of attaching the insulating member 152 on the first semiconductor die 140 as one of the intermediate steps of the example method for manufacturing the 3D IC structure 130.

Referring to FIG. 6, the insulating member 152 may be attached on the first semiconductor die 140. Thus, a stress between the first semiconductor die 140 and the second semiconductor die 150 may be relieved by disposing the insulating member 152. In an embodiment, the insulating member 152 may include a non-conductive film (NCF).

The non-conductive film (NCF) may have adhesiveness, and is attached on the first semiconductor die 140. The non-conductive film (NCF) may have an uncured state that may be deformed by an external force. The non-conductive film (NCF) may be attached by heating the non-conductive film (NCF) at a temperature of about 170° C. to about 300° C. for about 1 second to about 20 seconds.

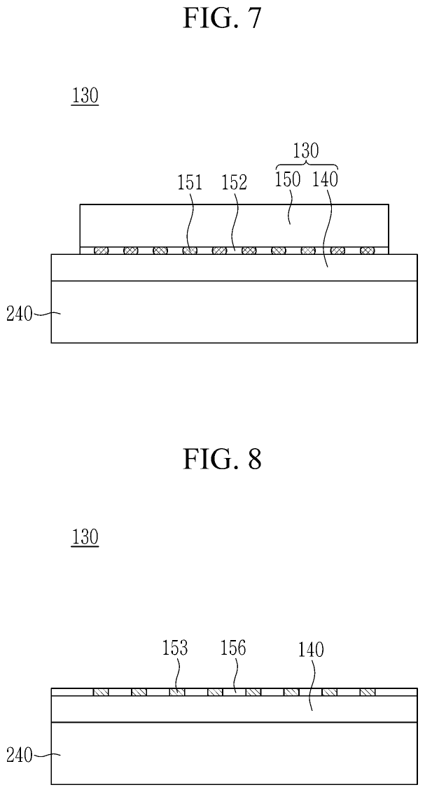

FIG. 7 is a cross-sectional view showing a step of mounting the second semiconductor die 150 on the first semiconductor die 140 as one of the intermediate steps of the example method for manufacturing the 3D IC structure 130.

Referring to FIG. 7, the second semiconductor die 150 is mounted on the first semiconductor die 140. The connection member 151 provided in the second semiconductor die 150 penetrates the insulating member 152 to contact the first semiconductor die 140.

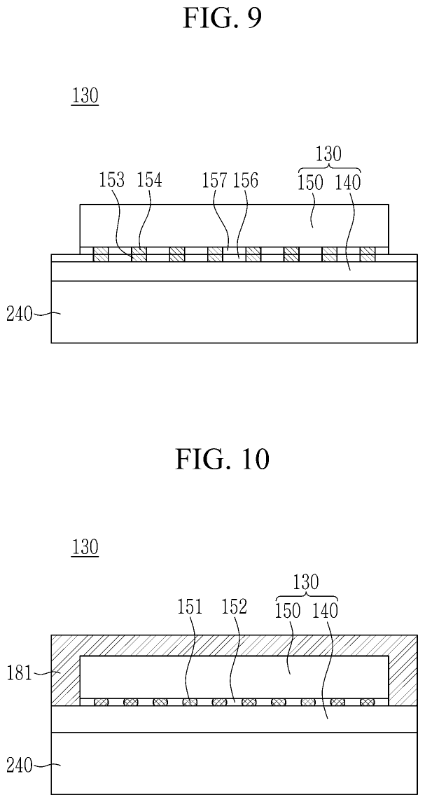

FIG. 8 is a cross-sectional view showing a step of attaching the first semiconductor die 140 on the first carrier 240 as one of the intermediate steps of the example method for manufacturing the 3D IC structure 130. FIGS. 8 and 9 are cross-sectional views showing the method for manufacturing the 3D IC structure 130 in which the first semiconductor die 140 and the second semiconductor die 150 are bonded by hybrid bonding.

Referring to FIG. 8, the first semiconductor die 140 is attached on the first carrier 240. The first carrier 240 may include a silicon-based material such as glass or a silicon oxide, another material such as an organic material or an aluminum oxide, any combination thereof, or the like. The first semiconductor die 140 may include the first bonding pads 153 and the first silicon insulating layer 156 on the upper surface of the first semiconductor die 140, the first silicon insulating layer 156 being disposed between adjacent first bonding pads 153.

FIG. 9 is a cross-sectional view showing a step of bonding the first semiconductor die 140 and the second semiconductor die 150 by hybrid bonding as one of the intermediate steps of the example method for manufacturing the 3D IC structure 130.

Referring to FIG. 9. the first semiconductor die 140 and the second semiconductor die 150 are bonded by performing hybrid bonding. The second semiconductor die 150 may include the second bonding pads 154 and the second silicon insulating layer 157 on the lower surface of the second semiconductor die 150. The first bonding pads 153 on the upper surface of the first semiconductor die 140 and the corresponding second bonding pads 154 on a lower surface of the second semiconductor die 150 may be aligned with one another in the vertical direction and directly bonded by the metal-metal hybrid bonding. Metal bonding is performed at an interface between the first bonding pad 153 on the upper surface of the first semiconductor die 140 and the corresponding second bonding pad 154 on the lower surface of the second semiconductor die 150 by the metal-metal hybrid bonding. In an embodiment, the first bonding pad 153 and the second bonding pad 154 may include copper. In another embodiment, the first bonding pad 153 and the second bonding pad 154 may be a metallic material to which the hybrid bonding may be applied.

The first bonding pads 153 on the upper surface of the first semiconductor die 140 and the second bonding pads 154 on the lower surface of the second semiconductor die 150 may be made of the same material so that after the hybrid bonding, there may be no interface between the first bonding pads 153 on the upper surface of the first semiconductor die 140 and the corresponding second bonding pads 154 on the lower surface of the second semiconductor die 150. The first semiconductor die 140 and the second semiconductor die 150 may be electrically connected to each other through the first bonding pads 153 on the upper surface of the first semiconductor die 140 and the second bonding pads 154 on the lower surface of the second semiconductor die 150.

The first silicon insulating layer 156 on the upper surface of the first semiconductor die 140 and the second silicon insulating layer 157 on the lower surface of the second semiconductor die 150 may be directly bonded by the non-metal-non-metal hybrid bonding. Covalent bonding may be performed at an interface between the first silicon insulating layer 156 on the upper surface of the first semiconductor die 140 and the second silicon insulating layer 157 on the lower surface of the second semiconductor die 150 by the non-metal-non-metal hybrid bonding.

In an embodiment, the first silicon insulating layer 156 and the second silicon insulating layer 157 may include a silicon oxide or a TEOS-formed oxide. In an embodiment, the first silicon insulating layer 156 and the second silicon insulating layer 157 may include SiO₂. In another embodiment, the first silicon insulating layer 156 and the second silicon insulating layer 157 may be a silicon nitride, a silicon oxynitride, or another suitable dielectric material. In another embodiment, the first silicon insulating layer 156 and the second silicon insulating layer 157 may include SiN or SiCN.

The first silicon insulating layer 156 on the upper surface of the first semiconductor die 140 and the second silicon insulating layer 157 on the lower surface of the second semiconductor die 150 may be made of the same material so that after the hybrid bonding, there may be no interface between the first silicon insulating layer 156 on the upper surface of the first semiconductor die 140 and the second silicon insulating layer 157 on the lower surface of the second semiconductor die 150.

The method for manufacturing the 3D IC structure 130 in which the first semiconductor die 140 and the second semiconductor die 150 are bonded by the flip-chip bonding of FIGS. 10 to 13 may be equally applied to manufacturing methods after FIG. 9 among the method for manufacturing the 3D IC structure 130 by hybrid bonding.

FIG. 10 is a cross-sectional view showing a step of molding (i.e., encapsulating) the second semiconductor die 150 on the first semiconductor die 140 with the second molding material 181 as one of the intermediate steps of the example method for manufacturing the 3D IC structure 130.

Referring to FIG. 10. the second semiconductor die 150 is molded on the first semiconductor die 140 with the second molding material 181, such that the second molding material 181 encapsulates or otherwise extends around the second semiconductor die 150. In an embodiment, a process of molding with the second molding material 181 may include a compression molding or transfer molding process.

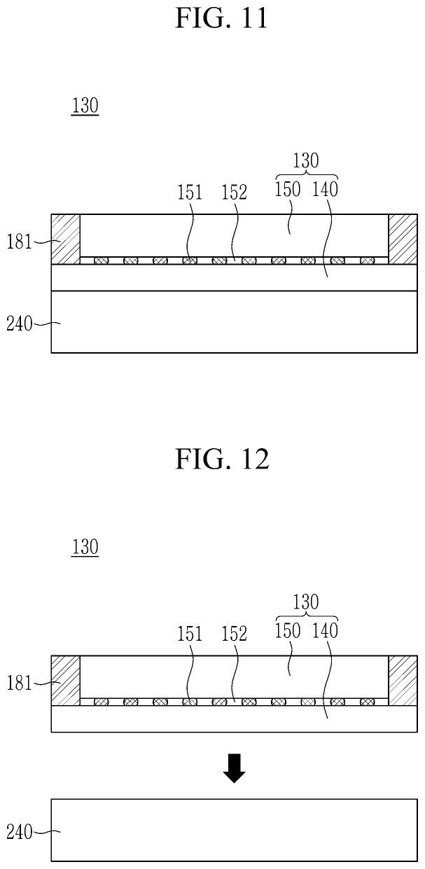

FIG. 11 is a cross-sectional view illustrating a step of planarizing an upper surface of the second molding material 181 as one of the intermediate steps of the example method for manufacturing the 3D IC structure 130.

Referring to FIG. 11, chemical mechanical polishing (CMP) may be performed to adjust a level of an upper surface of the second molding material 181, such that the upper surface of the second molding material 181 is coplanar with respect to the upper surface of the second semiconductor die 150. The upper surface of the second molding material 181 may be planarized by applying a CMP process, although embodiments of the present disclosure are not limited thereto.

FIG. 12 is a cross-sectional view illustrating a step of debonding (i.e., separating) the first carrier 240 from the 3D IC structure 130 as one of the intermediate steps of the example method for manufacturing the 3D IC structure 130.

Referring to FIG. 12, the first carrier 240 is debonded from the first semiconductor die 140 of the 3D IC structure 130.

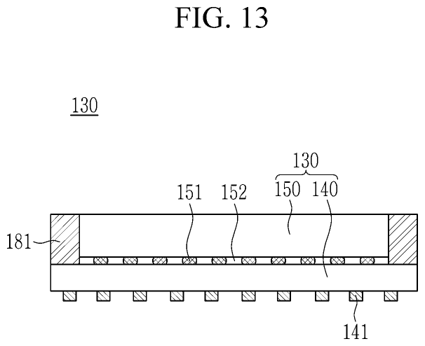

FIG. 13 is a cross-sectional view showing a step of forming connection terminals 141 on the lower surface of the first semiconductor die 140 as one of the intermediate steps of the example method for manufacturing the 3D IC structure 130.

Referring to FIG. 13. the connection terminals 141 may be formed on the lower surface of the first semiconductor die 140.

In an embodiment, the connection terminals 141 may be formed using a photoresist. First, the photoresist is coated on the lower surface of the first semiconductor die 140. In an embodiment, the photoresist may be formed through spin coating. In an embodiment, the photoresist may include an organic polymeric resin including a photoactive material. Next, the photoresist is exposed and developed to form a pattern of the photoresist. Then, a seed metal layer is formed at the pattern of the photoresist. In an embodiment, the seed metal layer may be formed by electroless plating or sputtering. Next, the connection terminals 141 are deposited using the seed metal layer. In an embodiment, the connection terminals 141 may be formed by electrolytic plating. In an embodiment, the connection terminals 141 may include at least one of copper, aluminum, silver, tin, gold, nickel, lead, titanium, and an alloy thereof, although embodiments are not limited thereto.

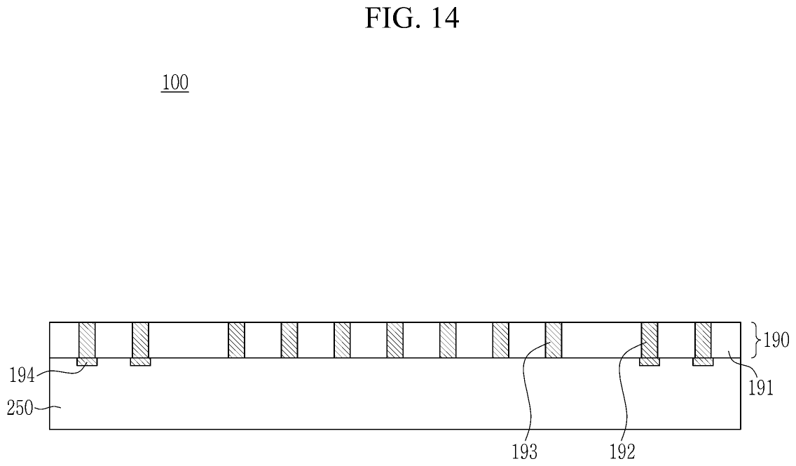

FIG. 14 is a cross-sectional view showing a step of attaching the silicon interposer 190 on a second carrier 250 as one of the intermediate steps of the example method for manufacturing the semiconductor package 100.

Referring to FIG. 14, the silicon interposer 190 is attached on the second carrier 250, so that a bottom (lower) surface of the silicon interposer 190 faces an upper surface of the second carrier 250. In attaching the silicon interposer 190 on the second carrier 250, the first through silicon vias 192 in the silicon interposer 190 are aligned with and contact corresponding connection pads 194 in the upper surface of second carrier 250.

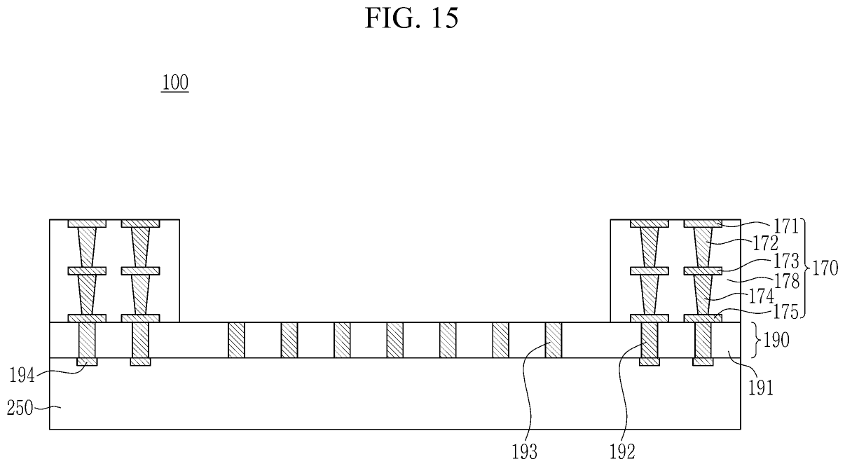

FIG. 15 is a cross-sectional view showing a step of attaching the printed circuit board 170 on the silicon interposer 190 as one of the intermediate steps of the example method for manufacturing the semiconductor package 100.

Referring to FIG. 15, the printed circuit board 170 is attached on the silicon interposer 190, so that an upper surface of the silicon interposer 190 faces a bottom (lower) surface of the printed circuit board 170. According to an embodiment, an attachment process between the silicon interposer 190 and the printed circuit board 170 may be performed by a method in which after a mask having openings through which the first through silicon vias (TSV) 192 are exposed is formed on the silicon interposer 190, a floating conductive pad (or a conductive pad) is formed by filling the opening with a conductive material and the third wire layer 175 of the printed circuit board 170 is attached to the conductive pad. In an embodiment, the conductive pad may include at least one of copper, aluminum, silver, tin, gold, nickel, lead, titanium, and an alloy thereof.

According to another embodiment, instead of a step of attaching the silicon interposer 190 on the second carrier 250 described with reference to FIG. 14, the silicon interposer 190 may be formed on the printed circuit board 170 by a method in which a step of attaching the second carrier 250 below the printed circuit board 170 is performed, and then a silicon layer is formed on the printed circuit board 170, and then a hole penetrating the silicon layer is formed and the hole is filled with a conductive material. In an embodiment, the hole formed in the silicon layer may be formed by deep etching. In another embodiment, the hole formed in the silicon layer may be formed by a laser. In an embodiment, the hole formed at the silicon layer may be filled with a conductive material by electrolytic plating to form the first through silicon vias (TSV) 192 and the second through silicon vias (TSV) 193. In an embodiment, the first through silicon vias (TSV) 192 and the second through silicon vias (TSV) 193 may include at least one of tungsten, aluminum, copper, and an alloy thereof.

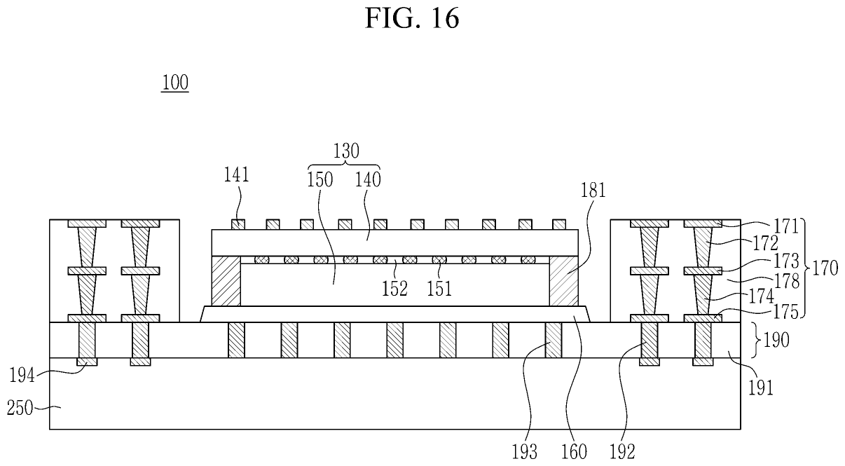

FIG. 16 is a cross-sectional view showing a step of attaching the 3D IC structure 130 including the connection terminals 141 on the silicon interposer 190 using the conductive adhesive member 160 as one of the intermediate steps of the example method for manufacturing the semiconductor package 100, and follows FIG. 15.

Referring to FIG. 16, the 3D IC structure 130 including the connection terminals 141 may be attached on the silicon interposer 190. The second semiconductor die 150 and the second molding material 181 may be attached above the silicon interposer 190 by the conductive adhesive member 160.

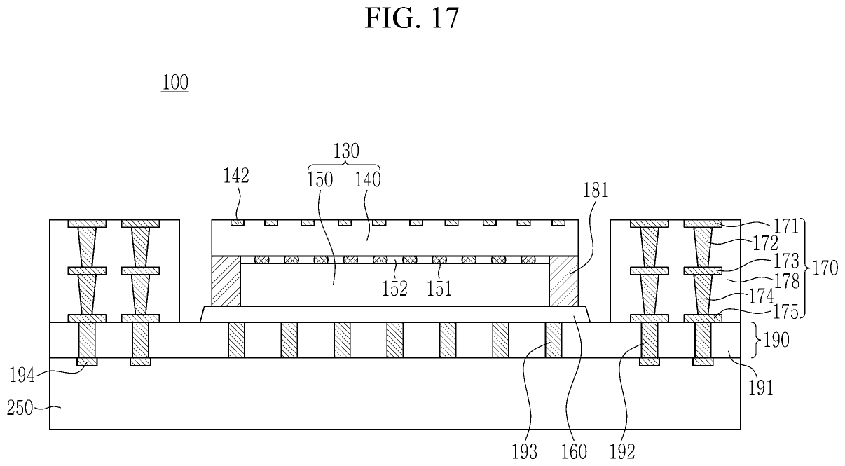

FIG. 17 is a cross-sectional view showing a step of attaching the 3D IC structure 130 not including the connection terminals 141 (see FIG. 16) on the silicon interposer 190 using the conductive adhesive member 160 as one of the intermediate steps of the example method for manufacturing the semiconductor package 100, and follows FIG. 15.

Referring to FIG. 17, the 3D IC structure 130 that does not include the connection terminals 141 (FIG. 16) and includes connection pads 142 may be attached on the silicon interposer 190. In an embodiment, the connection pads 142 may include at least one of copper, aluminum, silver, tin, gold, nickel, lead, titanium, and an alloy thereof.

Another configuration other than a configuration of FIG. 17 in which the 3D IC structure 130 that does not include the connection terminals 141 and includes the connection pads 142 is attached on the silicon interposer 190 is the same as the configuration described with reference to FIG. 16. Accordingly, the contents described with reference to FIG. 16 may be equally applied to the other configuration other than the configuration of FIG. 17 in which the 3D IC structure 130 that does not include the connection terminals 141 and includes the connection pads 142 is attached on the silicon interposer 190.

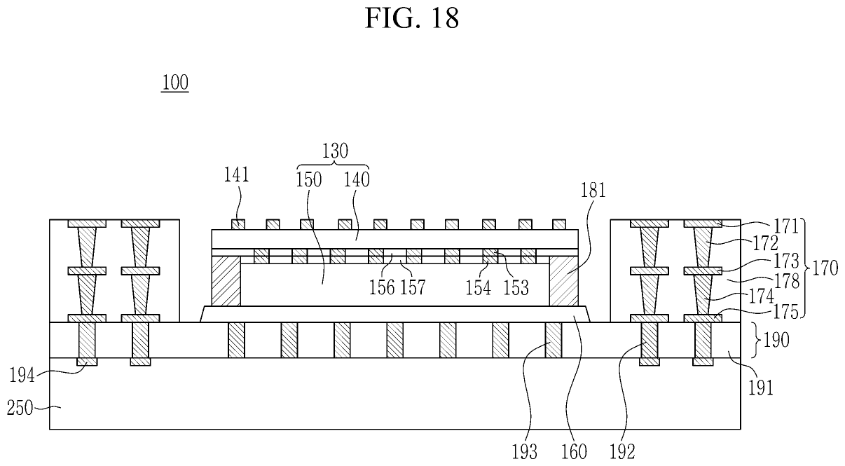

FIG. 18 is a cross-sectional view showing a step of attaching the 3D IC structure 130 in which the first semiconductor die 140 and the second semiconductor die 150 are bonded by hybrid bonding on the silicon interposer 190 using the conductive adhesive member 160 as one of the intermediate steps of the example method for manufacturing the semiconductor package 100, and follows FIG. 15.

Referring to FIG. 18, the 3D IC structure 130 in which the first semiconductor die 140 and the second semiconductor die 150 are bonded by hybrid bonding may be attached on the silicon interposer 190.

Another configuration other than a configuration of FIG. 18 in which the 3D IC structure 130 in which the first semiconductor die 140 and the second semiconductor die 150 are bonded by hybrid bonding is attached above the silicon interposer 190 is the same as the configuration described with reference to FIG. 16. Accordingly, the contents described with reference to FIG. 16 may be equally applied to the other configuration other than the configuration of FIG. 18 in which the 3D IC structure 130 in which the first semiconductor die 140 and the second semiconductor die 150 are bonded by the hybrid bonding is attached above the silicon interposer 190.

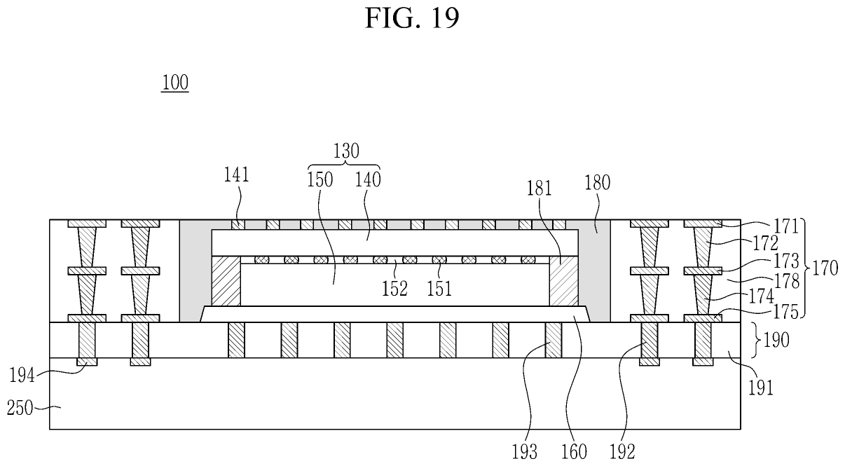

In addition, a manufacturing method of FIGS. 19 to 24 may be equally applied to a manufacturing method after FIG. 18 among the method for manufacturing the semiconductor package including the 3D IC structure bonded by hybrid bonding.

FIG. 19 is a cross-sectional view showing a step of molding (i.e., encapsulating) the 3D IC structure 130 including the connection terminals 141 with the first molding material 180 as one of the intermediate steps of the example method for manufacturing the semiconductor package 100, and follows FIG. 16.

Referring to FIG. 19, the 3D IC structure 130 is molded (i.e., encapsulated) with the first molding material 180 on the silicon interposer 190 and within the through opening of the printed circuit board 170. In an embodiment, a process of molding with the first molding material 180 may include a compression molding or transfer molding process.

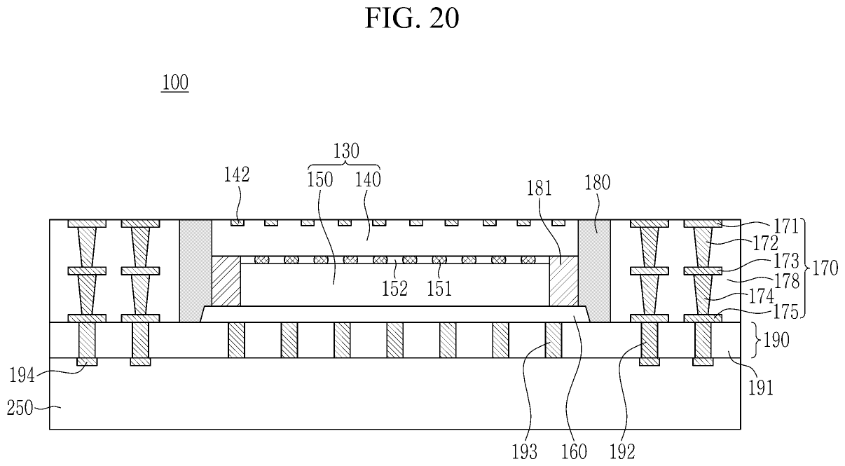

FIG. 20 is a cross-sectional view showing a step of molding the 3D IC structure not including the connection terminals 141 (FIG. 16) with the first molding material 180 as one of the intermediate steps of the example method for manufacturing the semiconductor package 100, and follows FIG. 17.

Referring to FIG. 20, on the silicon interposer 190 and within the through opening of the printed circuit board 170, a side surface of the first semiconductor die 140 of the 3D IC structure 130 and a side surface of the second molding material 181 are molded by the first molding material 180. In an embodiment, a process of molding with the first molding material 180 may include a compression molding or transfer molding process.

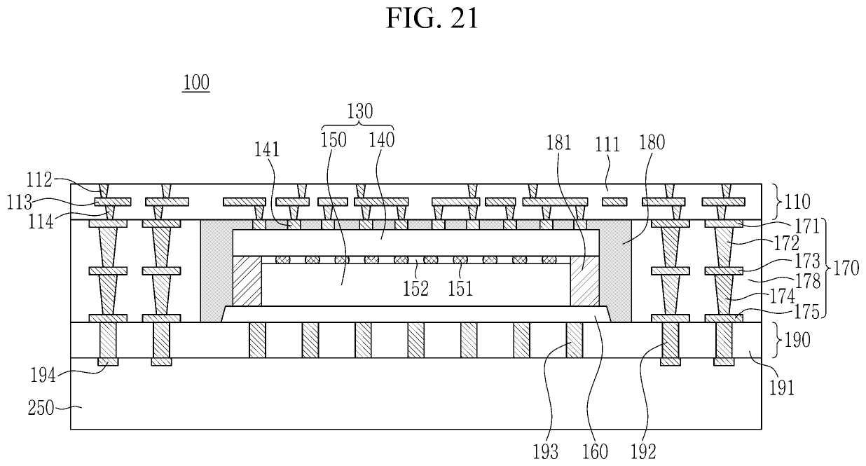

FIG. 21 is a cross-sectional view showing a step of forming the front side redistribution layer structure 110 on the first molding material 180 and the printed circuit board 170 as one of the intermediate steps of the example method for manufacturing the semiconductor package 100, and follows FIG. 19.

Referring to FIG. 21, the front-side redistribution layer structure 110 may be formed on the first molding material 180 and the printed circuit board 170.

First, the dielectric layer 111 is formed on the first molding material 180 and the printed circuit board 170. In an embodiment, the dielectric layer 111 may include a photosensitive polymer layer. The photosensitive polymer may be a material capable of forming a fine pattern by applying a photolithography process. In an embodiment, the dielectric layer 111 may include a photoimageable dielectric (PID) used in a redistribution layer process. As an embodiment, the photoimageable dielectric (PID) may include a polyimide-based photosensitive polymer, a novolac-based photosensitive polymer, polybenzoxazole, a silicone-based polymer, an acrylate-based polymer, or an epoxy-based polymer. In another embodiment, the dielectric layer 111 may be formed of a polymer such as PBO, polyimide, or the like. In another embodiment, the dielectric layer 111 may be formed of an inorganic dielectric material such as silicon nitride, silicon oxide, or the like. In an embodiment, the dielectric layer 111 may be formed by a chemical vapor deposition (CVD), atomic layer deposition (ALD), or plasma-enhanced chemical vapor deposition (PECVD) process.

After the dielectric layer 111 is formed, via holes are formed by selectively etching the dielectric layer 111, and the second redistribution layer vias 114 are formed by filling the via holes with a conductive material. A width, in the horizontal direction, of an uppermost portion of each second redistribution layer via among the second redistribution layer vias 114 may be greater than a width of a lowermost portion of each second redistribution layer via. Since the first semiconductor die 140 on which the front side redistribution layer structure 110 is formed is overturned (i.e., flipped upside down) to manufacture a final product in a subsequent process, the width, in the horizontal direction, of the uppermost portion of each second redistribution layer via among the second redistribution layer vias 114 may be smaller than the width of the lowermost portion of each second redistribution layer via in the final product.

Next, the dielectric layer 111 is additionally deposited on the second redistribution layer vias 114 and the dielectric layer 111, openings are formed by selectively etching the additionally deposited dielectric layer 111, and the first redistribution layer lines 113 are formed by filling the openings with conductive materials.

Then, the dielectric layer 111 is additionally deposited on the first redistribution layer lines 113 and the dielectric layer 111, the additionally deposited dielectric layer 111 is selectively etched to form via holes, and the via holes are filled with conductive materials to form the first redistribution layer vias 112. For the same reason that the width of the uppermost portion of each second redistribution layer via among the second redistribution layer vias 114 may be smaller than the width of the lowermost portion of each second redistribution layer via, a width of an uppermost portion of each first redistribution layer via 112 among the first redistribution layer vias 112 may be smaller than a width of a lowermost portion of each first redistribution layer via 112 in the final product.

In an embodiment, the first redistribution layer vias 112, the first redistribution layer lines 113, and the second redistribution layer vias 114 may include at least one of copper, aluminum, tungsten, nickel, gold, tin, titanium, and an alloy thereof. In an embodiment, the first redistribution layer vias 112, the first redistribution layer lines 113, and the second redistribution layer vias 114 may be formed by performing a sputtering process. In another embodiment, the first redistribution layer vias 112, the first redistribution layer lines 113, and the second redistribution layer vias 114 may be formed by performing an electroplating process after forming a seed metal layer.

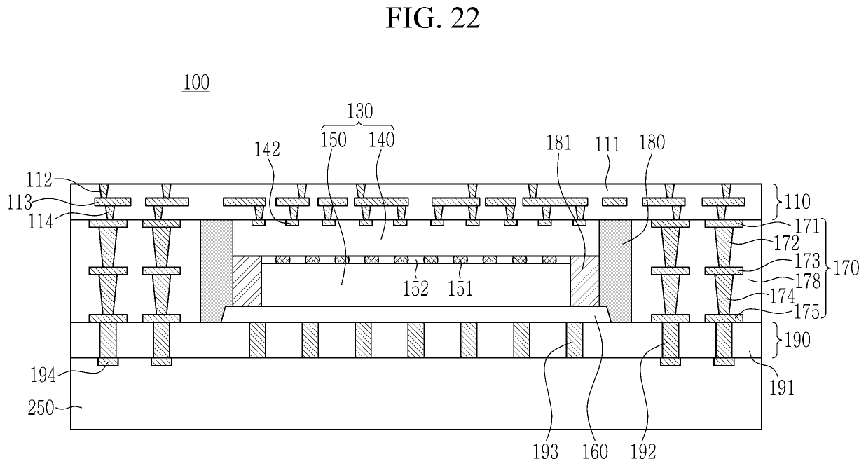

FIG. 22 is a cross-sectional view showing a step of forming the front-side redistribution layer structure 110 to be directly bonded with a lower surface of the 3D IC structure 130 on the first molding material 180 and the printed circuit board 170 as one of the intermediate steps of the example method for manufacturing the semiconductor package 100, and follows FIG. 20.

Referring to FIG. 22, the front side redistribution layer structure 110 may be formed on the first semiconductor die 140, the printed circuit board 170, and the first molding material 180. According to the embodiment of FIG. 22, since the dielectric layer 111 is directly formed on the first semiconductor die 140, a connection member such as a micro-bump, a solder bump, or the like may not be required between the first semiconductor die 140 and the front side redistribution layer structure 110, and may therefore be omitted. The second redistribution layer vias 114 disposed at a level of (i.e., coplanar with) an uppermost portion of the front-side redistribution layer structure 110 may be directly bonded to the 3D IC structure 130.

Another configuration other than a configuration of FIG. 22 in which the 3D IC structure 130 that does not include the connection terminals 141 (FIG. 16) and includes the connection pads 142 is attached above the silicon interposer 190 is the same as the configuration described with reference to FIG. 21. Accordingly, the contents described with reference to FIG. 21 may be equally applied to the other configuration other than the configuration of FIG. 22 in which the 3D IC structure 130 that does not include the connection terminals 141 (FIG. 16) and includes the connection pads 142 is attached above the silicon interposer 190.

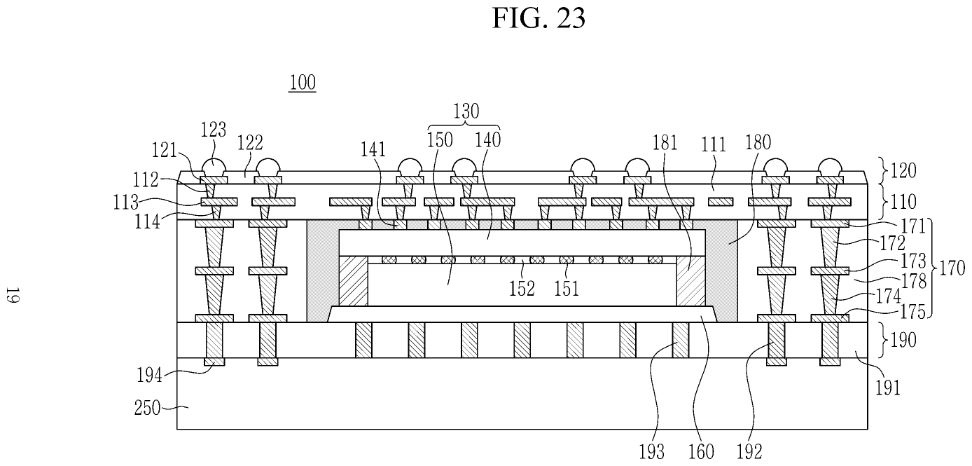

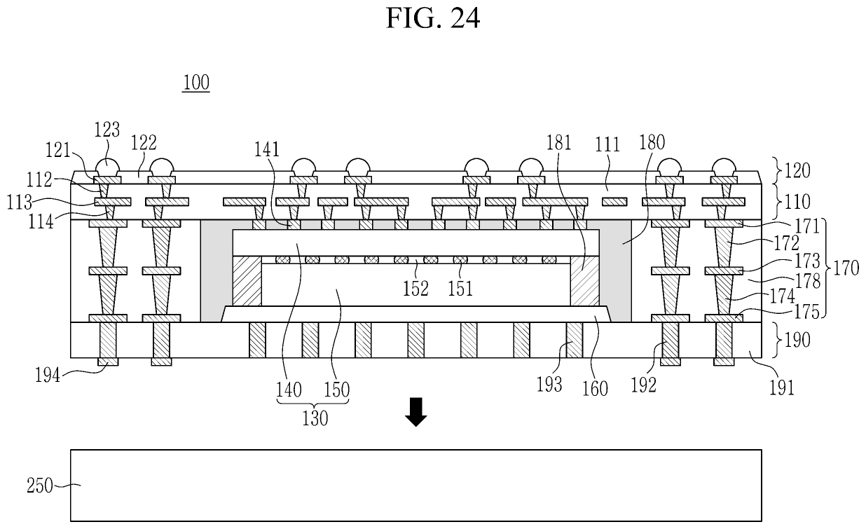

On the other hand, a manufacturing method of FIGS. 23 and 24 may be equally applied to a manufacturing method after FIG. 22 among the method for manufacturing the semiconductor package including the 3D IC structure that does not include the connection terminals 141 (FIG. 16).

FIG. 23 is a cross-sectional view showing a step of forming the external connection structure 120 on the front-side redistribution layer structure 110 as one of the intermediate steps of the example method for manufacturing the semiconductor package 100, and follows FIG. 21.

Referring to FIG. 23, the external connection structure 120 may be formed on the front-side redistribution layer structure 110. The insulating layer 122 may be formed on the dielectric layer 111 of the front-side redistribution layer structure 110, and the conductive pads 121 may be formed on the first redistribution layer vias 112. In an embodiment, the conductive pads 121 may include at least one of copper, nickel, zinc, gold, silver, platinum, palladium, chromium, titanium, and an alloy thereof. In an embodiment, the insulating layer 122 may include a solder resist. In an embodiment, the external connection members 123 may include at least one of tin, silver, lead, nickel, copper, or an alloy thereof. In an embodiment, the conductive pads 121 may be formed by performing a sputtering process, or may be formed by performing an electroplating process after forming a seed metal layer. In an embodiment, the insulating layer 122 may be formed by a CVD, ALD, or PECVD process.

FIG. 24 is a cross-sectional view showing a step of debonding the second carrier 250 from the silicon interposer 190 as one of the intermediate steps of the example method for manufacturing the semiconductor package 100.

Referring to FIG. 24, the second carrier 250 is debonded (i.e., separated) from the silicon interposer 190.

After that, the memory structure 210 is mounted on the silicon interposer 190.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor package, comprising:
a redistribution layer structure;
a semiconductor structure on the redistribution layer structure;
a printed circuit board on the redistribution layer structure and extending around a side surface of the semiconductor structure;
a molding material extending around the semiconductor structure on the redistribution layer structure; and
a silicon interposer on the printed circuit board and the molding material.

2. The semiconductor package of claim 1, wherein a thermal conductivity of the silicon interposer is higher than a thermal conductivity of the redistribution layer structure.

3. The semiconductor package of claim 1, wherein the silicon interposer includes a plurality of first through silicon vias.

4. The semiconductor package of claim 3, wherein the printed circuit board is configured to electrically connect the redistribution layer structure and the plurality of first through silicon vias.

5. The semiconductor package of claim 3, wherein the silicon interposer includes a heat dissipation structure comprising a plurality of second through silicon vias.

6. The semiconductor package of claim 5, wherein each of at least a subset of the plurality of second through silicon vias are electrically insulated.

7. The semiconductor package of claim 1, wherein the printed circuit board includes an embedded trace substrate (ETS).

8. The semiconductor package of claim 1, wherein the printed circuit board includes an opening, and the semiconductor structure is within the opening.

9. The semiconductor package of claim 1, wherein the semiconductor structure includes a three dimensional integrated circuit (3D IC) structure including a first semiconductor die and a second semiconductor die on the first semiconductor die.

10. The semiconductor package of claim 9, further comprising:
a connection member between the first semiconductor die and the second semiconductor die; and
an insulating member between the first semiconductor die and the second semiconductor die and extending around the connection member.

11. The semiconductor package of claim 10, wherein the connection member includes a micro-bump.

12. The semiconductor package of claim 10, wherein the insulating member includes a non-conductive film (NCF).

13. The semiconductor package of claim 1, wherein the redistribution layer structure includes a plurality of redistribution layer vias, at least a subset of the redistribution layer vias at a level of an uppermost portion of the redistribution layer structure being directly bonded to the semiconductor structure.

14. The semiconductor package of claim 13, wherein each redistribution layer via among the plurality of redistribution layer vias has a width, in a horizontal direction parallel to an upper surface of the redistribution layer structure, of an uppermost portion of the redistribution layer via that is smaller than a width of a lowermost portion of the redistribution layer via.

15. A semiconductor package, comprising:
a redistribution layer structure;
a first semiconductor structure on the redistribution layer structure;
a conductive adhesive member on the first semiconductor structure;
a printed circuit board on the redistribution layer structure and extending around a side surface of the first semiconductor structure;
a molding material extending around the first semiconductor structure on the redistribution layer structure;
a silicon interposer on the conductive adhesive member, the printed circuit board, and the molding material; and
a second semiconductor structure on the silicon interposer.

16. The semiconductor package of claim 15, wherein the conductive adhesive member includes a thermal interface material (TIM).

17. The semiconductor package of claim 15, wherein the first semiconductor structure includes a system-on-chip (SoC).

18. The semiconductor package of claim 15, wherein the second semiconductor structure includes at least one of a dynamic random-access memory (DRAM) and a high-bandwidth memory (HBM).

19. A method for manufacturing a semiconductor package, comprising:
attaching a printed circuit board including a through opening to a first surface of a silicon interposer;
attaching a semiconductor structure to the first surface of the silicon interposer and within the through opening with a conductive adhesive member;
encapsulating the semiconductor structure with a molding material; and
forming a redistribution layer structure on the molding material and the printed circuit board.

20. The method of claim 19, further comprising mounting a memory structure on a second surface of the silicon interposer opposite to the first surface of the silicon interposer.
